(19) United States
(12) Patent Application Publication
(10) Pub. No.: US 2007/0147572 A1
(43) Pub. Date: Jun. 28, 2007

(54) Registers for an enhanced idle architectural state

(75) Inventors: Aurobindo Dasgupta, Austin, TX (US); Amit Bhalerao, Bangalore (IN)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 11/320,429

(22) Filed: Dec. 28, 2005

(51) Int. Cl. G11C 19/00

(52) U.S. Cl. 377/64

(57) ABSTRACT

Some embodiments of the invention include apparatus, systems, and methods to force values to output nodes of registers of at least one circuit unit of a device during an idle state to reduce leakage power in the circuit unit. Other embodiments are described and claimed.

### FIELD

Embodiments of the present invention relate generally to power management in electronic devices, and particularly to managing power during an idle state in electronic devices.

### BACKGROUND

Many electronic devices such as computers and cellular phones, have an active state and an idle state. A device may perform some functions during the active state. When no function is required, the device may be in the idle state or a lower power state to save power. In some cases, although the device may be in the idle state, some components of the device may cause undesirable leakage power, thereby wasting power.

### BRIEF DESCRIPTION OF DRAWINGS

FIG. 1 shows an apparatus according to an embodiment of the invention.

FIG. 2 shows a timing diagram for FIG. 1.

FIG. 3 shows a register according to an embodiment of the invention.

FIG. 4 shows a register with output gating according to an embodiment of the invention.

FIG. 5 through FIG. 9 show registers with output gating according to other embodiments of the invention.

FIG. 10 and FIG. 11 show registers with an isolation logic circuit according to some embodiments of the invention.

FIG. 12 shows an example of a system according to an embodiment of the invention.

FIG. 13 is a flowchart showing a method according to an embodiment of the invention.

### DESCRIPTION OF EMBODIMENTS

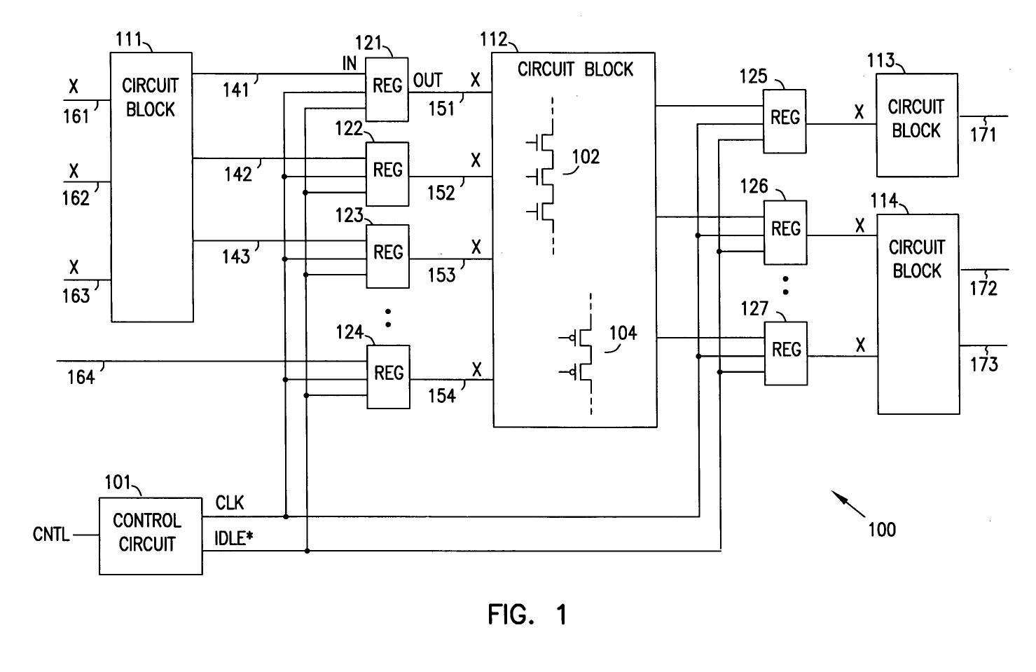

FIG. 1 shows an apparatus according to an embodiment of the invention. Apparatus or circuit unit 100 may reside in an electronic device such as a desktop computer, a laptop or notebook computer, a cellular phone, a personal digital assistant (PDA), or other electronic devices. Circuit unit 100 is configured to reduce leakage power that may occur during an idle state of circuit unit 100.

Circuit unit 100 includes circuit blocks 111, 112, 113, and 114, registers (REG) 121 to 127 (121, 122, 123, 124, 125, 126, and 127), and a control circuit 101. The signal lines in FIG. 1 allow communication between registers 121 to 127 and circuit blocks 111 to 114. For example, signal lines 141, 142, and 143 allow circuit block 111 to provide an input value (IN) to each of the registers 121 to 123. Lines 151, 152, 153, and 154 allow each ofthe registers 121 to 124 to provide an output value (OUT) from the register output node to the input node of circuit block 112. In some embodiments, circuit unit 100 uses lines 161, 162, 163, and 164 to receive input values from one or more other circuits and uses lines 171, 172, and 173 to provide output values to one or more other circuits. In some embodiments, circuit unit 100 includes other registers, circuit blocks, and signal lines.

In the description herein, a value at a node (line) refers to the value of a signal level of the signal at the node. For example, the input value of register 121 refers to the value of the signal on input node 141 of register 121; the output value of register 121 refers to the value of the signal on output node 151 of register 121. Since a line in FIG. 1 may be coupled between an output node of a register and an input node of a circuit block, the output value of a register may also be the input value of the circuit block. For example, the output value at node 151 of register 121 is also the input value at node 151 of circuit block 112. Although FIG. 1 shows seven registers 121 to 127 as an example, in some embodiments, circuit unit 100 includes a different number of registers. Although FIG. I shows four circuit blocks 111 to 114 as an example, in some embodiments, the number of the circuit blocks is different from four.

In some embodiments, each of the circuit blocks 111 to 114 is a functional unit block and includes a circuit such as a combinational circuit to perform a function on input values provided at the input nodes of the circuit block. For example, in some embodiments, circuit block 112 performs a function on input values provided at nodes 151 to 154. In some embodiments, one or more of the circuit blocks 111 to 114 are an adder, a multiplier, a comparator, or other types of circuits.

Control circuit 101 provides a clock signal CLK and a control signal IDLE* to registers 121 to 127. Control circuit 101 responds to control information CNTL to apply appropriate signal levels to the CLK and IDLE* signals during an active state and an idle state of circuit unit 100. In some embodiments, CNTL indicates when circuit unit 100 is in the active state and when circuit unit 100 is in the idle state. In some embodiments, in the active state, at least one portion of circuit unit 100 actively performs a function such as addition, multiplication, or other functions. In some embodiments, in the idle state, a portion or the entire circuit unit 100 is inactive or idle. In some embodiments, CNTL is one or more signals at system level provided by a system that uses circuit unit 100. In other embodiments, CNTL is one or more signals at local level generated by circuit unit 100. In some embodiments, control circuit 101 resides outside circuit unit 100.

In some embodiments, the CLK signal is a gated clock signal such that the CLK signal periodically switches between low and high signal levels during the active state and remains at one level (either low or high) during the idle state. In some embodiments, the IDLE* signal has one signal level corresponding to the active state and another signal level corresponding the idle state.

Each of the circuit blocks 111 to 114 may include numerous transistors. The number of transistors in each of the circuit blocks may be hundreds or thousands. Two or more transistors in circuit blocks 111 to 114 may be connected in series to form a transistor stack. For example, circuit block 112 may include a transistor stack 102 having three transistors connected in series, and a transistor stack 104 having two transistor connected in series. In some embodiments, many other transistor stacks similar to transistor stacks 102 and 104 exist in circuit block 112 and in other circuit blocks 111, 113, and 114. In some embodiments, the transistor stacks in circuit blocks 111 to 114 are a part of a functional circuit such as an adder, a multiplier, a comparator, or other types of circuits. The transistors in transistor stacks 102 and 104 are p-channel and n-channel metal oxide semiconductor field effect transistors (MOSFET). Other types of transistors may be used. In some embodiments, the values at the output nodes of registers 121 to 127 are provided to the gates of the transistors in the transistor stacks of circuit blocks 111 to 114.

In some embodiments, when circuit unit 100 is in the active state (when the IDLE* signal has a signal level corresponding to the active state), the input value received at the input node of the register is provided to the output node of the register as the output value. For example, during the active state in some embodiments, the input value IN received at input node 141 of register 121 is provided to output node 151 of the register as the output value OUT. Register 121 may provide the output value at node 151 to circuit block 112 during the active state for processing.

In some embodiments, when circuit unit 100 is in the idle state (when the IDLE* signal has a signal level corresponding to the idle state), the input value received at the input node of the register is not provided to the output node of the register. For example, during the idle state in some embodiments, the input value received at input node 141 of register is not provided to output node 151; the input value is stored or retained in register 121 as a stored value. In the idle state, the output node of the register such as register 121 is forced or driven to a forced value to reduce leakage power in circuit block 112. In some embodiments, the forced value is a predetermined value and is based on a value of an input vector. The input vector is described below.

In circuit blocks 111 to 114, leakage power (leakage current) may occur in the transistors or in the transistor stacks of circuit blocks 111 to 114 during the idle state. For example, in the idle state, leakage power may occur in a path between supply nodes in which the path may be formed by the series connected transistors in the transistor stack such as transistor stacks 102 and 104.

In circuit unit 100, to reduce leakage power during the idle state, predetermined or forced values may be applied to the input nodes of each of the circuit blocks 111 to 114 during the idle state. For example, forced values may be applied to nodes 151 to 154 to reduce leakage power in circuit block 112 during the idle state. In some embodiments, the input nodes of each circuit block, such as nodes 151 to 154 of circuit block 112, are connected to the gates of the transistors of the transistor stacks in the circuit block. The forced values at the input nodes of each circuit block, for example circuit block 112, during the idle state may cause some combination of the transistors in the transistor stacks of circuit block 112 to turn off such that a reduction in leakage power in circuit 100 may be obtained.

In FIG. 1, nodes X represent both the input nodes of a circuit block and the output nodes of the corresponding registers. For example, nodes X on lines 151 to 154 represent the input nodes of circuit block 112 and the output nodes of corresponding registers 121 to 124. As described above, to reduce the leakage power during the idle state, forced values may be applied or forced to the input nodes of circuit blocks 111 to 114. In some embodiments, the forced values are applied at nodes X in which the forced value at each node X is a binary zero value (logical zero) or a binary one value (logical one).

In some embodiments, the forced values at nodes X are based on a value of an input vector. The input vector described herein refers to an input combination of binary zeros and ones corresponding to a number of input nodes of a circuit unit, in which the input combination is applied in parallel to the number of the input nodes of the circuit unit.

In some embodiments, the value of the input vector is obtained during a leakage evaluation process. The leakage evaluation process may be performed by use of software or by other techniques. In some embodiments, the leakage evaluation process includes one or more of analyzing the configuration or structure of circuit blocks 111 to 114, applying test input vectors with different input combinations (ones and zeros) to the input nodes of each of the circuit blocks 111 to 114, and measuring the leakage power of each of the circuit blocks 111 to 114 in response to the test input vectors at each circuit block.

The leakage measurement may identify among the test input vectors one input vector that causes the circuit block to encounter the least leakage power in comparison with the other test input vectors. After such an input vector is identified, power may be saved (during a state such as the idle state) by forcing the input nodes of the circuit block with the forced value corresponding to the value of the identified input vector. For example, after the leakage evaluation process described above, the input vector corresponding to nodes 151, 152, 153, and 154 may have a binary value of 1001. Thus, in this example, leakage power may be reduced during the idle state by forcing an input vector of 1001 at nodes 151, 152, 153, and 154, respectively. Since nodes 151, 152, 153, and 154 are also output nodes of registers 121 to 124, forcing 1001 at nodes 151, 152, 153, and 154 during the idle state (in this example) also means forcing a vector of 1001 at the output nodes of registers 121, 122, 123, and 124, respectively.

Thus, in the embodiments represented by FIG. 1, the forced value at the output node of each register in the idle state is based on the value of the input vector. The forced value at the output node of each register in the idle state is not based on the input value of the register, the stored value of the register, or the output value of the register before the idle state. Thus, in the embodiments represented by FIG. 1, the forced value at the output node of each register is independent of the input value of the register, the value stored in the register, or the output value at the output node of the register before the idle state. In other terms, in the embodiments represented by FIG. 1, regardless of the input value, the stored value, or the output value of the register before the idle state, the output node of the register is forced with a forced value based on the value of an input vector.

During the idle state in the embodiments represented by FIG. 1, forcing the output node of a register with a forced value independent of the input value, the stored value, or the output value of the register, causes the input nodes of a circuit block to quickly have a value corresponding to the value of the input vector. Thus, the circuit block may quickly reduce the leakage power after the idle state in initiated.

In some embodiments, the value stored in the register, such as register 121, is restored to a previous value when circuit unit 100 switches from the idle state to the active state. The previous value in the register is the value in the register before circuit unit 100 switches to the idle state. In some embodiments, the output node (node X in FIG. 1) of each register is restored to a previous output value when circuit unit 100 switches to the active state from the idle state. For example, if the output value of register 121 is a binary zero value before the idle state and is forced with a forced value of a binary one value during the idle state, the output of register 121 is restored to the previous binary zero value when circuit unit 100 switches to the active state from the idle state.

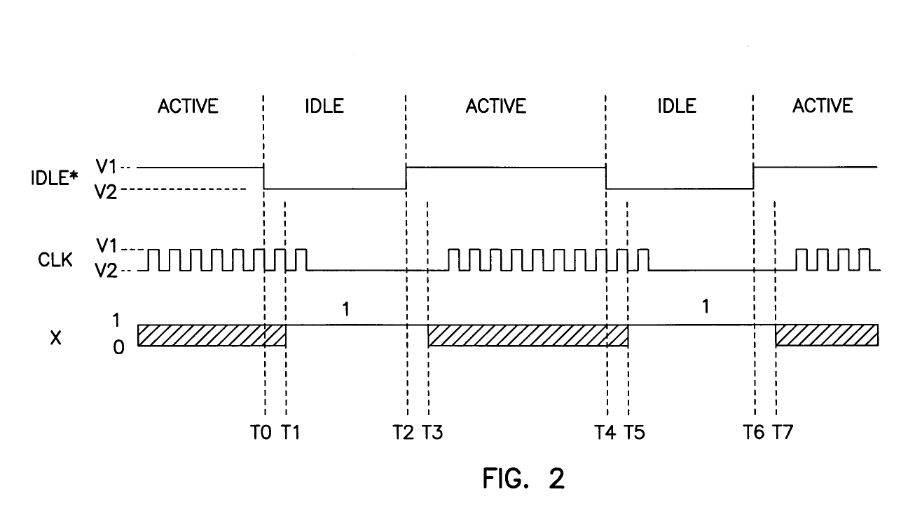

FIG. 2 is a timing diagram for FIG. 1. FIG. 2 shows examples of signal levels of the IDLE* signal, the CLK signal, and the value at node X. Node X in FIG. 2 represents one of the nodes X in FIG. 1. For example, node X in FIG. 2 may represent node X at the output node of register 121 at node 151. In FIG. 2, V1 and V2 represent different signal levels or values of the IDLE* and CLK signals. In some embodiments, V1 and V2 are voltage levels. In FIG. 2, values 0 and 1 at node X represent a binary zero value and a binary one value of node X during the active and idle states. During each active state in FIG. 2, node X may have either a binary zero value or a binary one value. The shaded area in FIG. 2 of node X in the active state means that node X may have either a binary zero value or a binary one value.

As shown in FIG. 2, the IDLE* signal has a first value V1 during the active state and a second value V2 during the idle state. The CLK signal switches between V1 and V2 during the active state and remains at one signal level during the idle state. In FIG. 2 the CLK signal remains at V2 level during the idle state, as an example. In some embodiments, the CLK signal may remain at V1 level during the idle state.

In FIG. 2, at time TO, the IDLE* signal switches from V1 to V2 to indicate a transition or switch from the active state to the idle state. Node X is forced to a forced value of a binary one at time T1. The forced value of a binary one at T1 may be based on a value of the input vector as described in FIG. 1. In some embodiments, the forced value may be a binary zero value at time T1.

As shown in FIG. 2, T1 is one clock cycle from TO. Thus, node X has a forced value (binary one) in one cycle after the IDLE* signal switches from V1 in the active state to V2 in the idle state. Forcing a forced value to node X in one cycle after the IDLE* signal switches from V1 to V2 allows a circuit block, such as circuit block 112 of FIG. 1, to quickly reduce leakage power after the idle state is initiated at time T0. FIG. 2 also shows another transition from the active state to the idle state at time T4. In the transition at T4, node X is forced to a binary one value at T5, which is one clock cycle from T4.

FIG. 2 further shows a transition from the idle state to the active state at time T2 and at time T6. In the transition at time T2, node X may be restored to a value that existed on node X before the IDLE* signal switches to the idle state at time TO. In the transition at time T6, node X may be restored to a value that existed on node X before the IDLE* signal switches to the idle state at time T4.

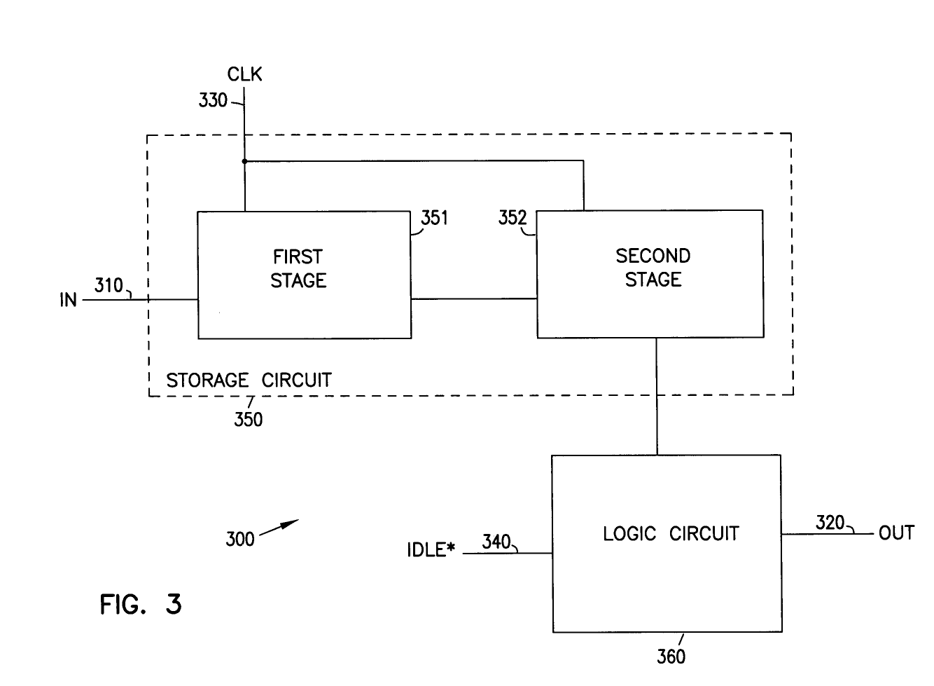

As described above in FIG. 1 and FIG. 2, leakage power may be reduced in a given state of circuit unit 100, for example in the idle state, by forcing a binary value of zero or one to the output nodes of registers 121 to 127. In some embodiments, the forced values at the output nodes of registers 121 to 127 are based on an input vector in which the input vector is identified from a leakage evaluation of circuit blocks 111 to 114. After the input vector is identified or determined, each of the registers 121 to 127 may be configured or constructed such that during the idle state, the output node of each of the registers 121 to 127 may be forced to a forced value (zero or one) corresponding to the value of the input vector to reduce leakage power in circuit blocks 112 to 114 during the idle state. FIG. 3 through FIG. 11 shows some embodiments of registers that may force a binary value of zero or one to the output node of the register during an idle state. In some embodiments, the registers shown in FIG. 3 through FIG. 11 are used as registers 121 to 127 of circuit unit 100 of FIG. 1.

FIG. 3 shows a register according to an embodiment of the invention. Register 300 includes an input node 310 to receive an input signal IN, an output node 320 to provide an output signal OUT, a clock node 330 to receive a clock signal CLK, and a control node 340 to receive a control signal IDLE*. The IN signal may be a data signal carrying data information to register 300. The CLK signal allows register 300 to pass the data information from input node 310 to output node 320. The IDLE* signal is provided by a control circuit such as control circuit 101 of FIG. 1. The IDLE* signal includes signal levels or values corresponding to an active state and an idle state. The OUT signal carries data information provided by register 300. The OUT signal may carry an output value dependent on the input value at input node 310 during the active state and a forced value independent of the input value during the idle state. The value at output node 320 may be used as input value of another circuit such as circuit block 112 of FIG. 1.

A storage circuit 350 includes a first stage 351 and a second stage 352 to store a stored value. The stored value corresponds to the input value at input node 310. In some embodiments, first stage and second stage may form a master and slave configuration of a flip flop. A logic circuit 360 responds to the stored value in storage circuit 350 and the value of the IDLE* signal to provide an output value to output node 320 during the active state and to provide a forced value to output node 320 during the idle state. The output value at output node 320 during the active state is dependent on the stored value in storage circuit 350. The forced value at output node during the idle state is independent of the stored value. Thus, output node 320 may have different values during the active state and the idle state.

In some embodiments, register 300 is configured or constructed to provide the forced value to output node 320 during the idle state in which the forced value is based on a value of an input vector. In some embodiments, the value of the input vector is determined during an evaluation such as the leakage evaluation described in FIG. 1. Thus, depending on the location of register 300 in a circuit unit such as circuit unit 100 of FIG. 1, register 300 may force either a binary zero value or a binary one value to output node 320. For example, if the input vector corresponding to nodes 151, 152, 152, and 153 of FIG. 1 is 1001, register 300 of FIG. 3 may be configured to force a binary one value at output node 320 during the idle state when register 300 is used as register 121 (coupled to node 151) of FIG. 1. In this example, register 300 of FIG. 3 may alternatively be configured to force a binary zero value at output node 320 during the idle state when register 300 is used as register 122 (coupled to node 152).

In some embodiments, register 300 is configured to restore the stored value in register 300 to a previous stored value. The previous stored value is the stored value before the idle state. In some embodiments, register 300 is configured to restore output node 320 to a previous output value that existed at output node before the idle state.

As described in FIG. 1 and FIG. 2, forcing a forced value based on the value of the input vector to an input of a circuit block, such as circuit block 112 of FIG. 1, during an idle state may reduce leakage power in the circuit block during the idle state. Since register 300 may be configured to force a forced value based on the value of the input vector to an input of a circuit block such as circuit block 112, using register 300 to force a forced value to the input node of a circuit block, such as circuit block, 112 may reduce leakage power in the circuit block during the idle state.

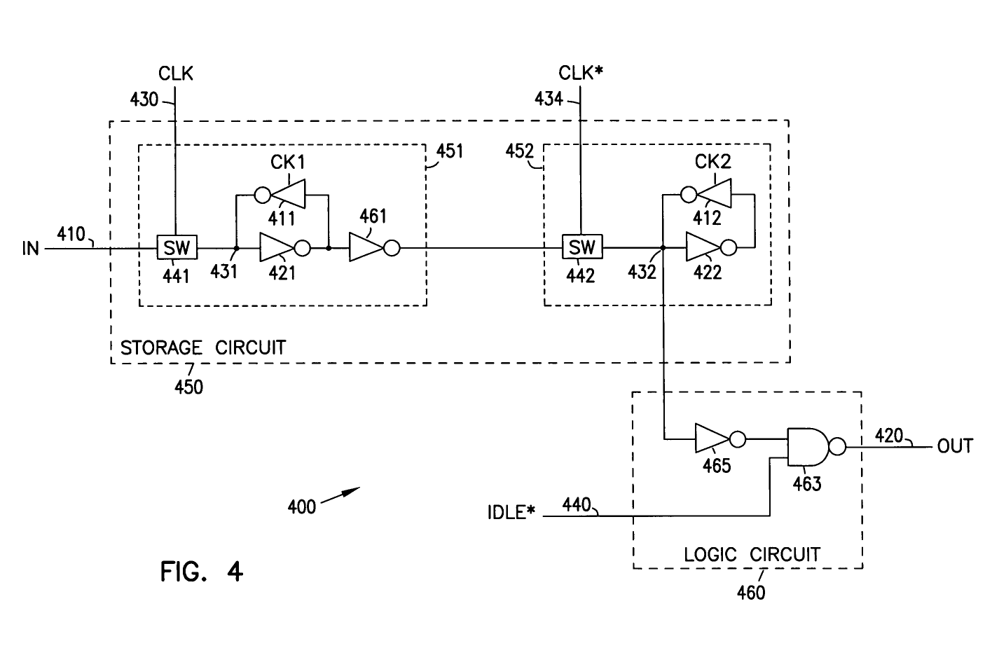

FIG. 4 shows a register with output gating according to an embodiment of the invention. Register 400 includes an input node 410 to receive an input signal IN, an output node 420 to provide an output signal OUT, a clock node 430 to receive a clock signal CLK, a clock node 434 to receive a clock signal CLK*, and a control node 440 to receive a control signal IDLE*. In some embodiments, the CLK and CLK* signals are complementary signals such that the CLK* signal is an inverse of the CLK signal.

A storage circuit 450 includes a first stage 451 and a second stage 452. First stage 451 includes a pair of inverters 411 and 421 arranged to form a first stage storage node 431 to store a stored value. The stored value at node 431 is based on the value of the IN signal. First stage 451 also includes a switch (SW) 441 and an inverter 461 coupled in series between input node 410 and second stage 452 to pass the input value to second stage 452 in response to the CLK signal. Second stage 452 includes a pair of inverters 412 and 422 arranged to form a second stage storage node 432 to store a stored value. The stored value at node 432 is based on the stored value at node 431. Second stage 452 also includes a switch (SW) 442 responsive to the CLK* signal to allow second stage 452 to receive the input value passed from first stage 451. Switches 441 and 442 respond to the CLK and CLK* signals such that when one switch turns on, the other switch turns off. For example, when switch 441 turns on, switch 442 turns off, and vice versa. In some embodiments, each of the switches 441 and 442 includes a transmission gate having a pair of p-channel and n-channel transistors, a single pass transistor, or other types of switches. Inverter 411 responds to a signal CK1 signal such that inverter 411 turns off to cut off a conducting path between the input and output nodes of inverter 411 when switch 441 turns on to receive the input value from node 410. In some embodiments, the CK1 signal is derived from the CLK* or CLK signal. In some embodiments, the CK1 signal is the same as the CLK* or CLK signal. Inverter 412 responds to a signal CK2 signal such that inverter 412 turns off to cut off a conducting path between the input and output nodes of inverter 412 when switch 442 turns on to receive the input value from first stage 451. In some embodiments, the CK2 signal is derived from the CLK or CLK* signal. In some embodiments, the CK2 signal is the same as the CLK or CLK* signal.

A logic circuit 460 includes an inverter 465 and a NAND gate 463, both connected in series with output node 420. Logic circuit 460 responds to the IDLE* signal to provide an output value to output node 420 during the active state and to force a forced value to output node 420 during the idle state. The output value at output node 420 during the active state is dependent on the stored value node at 431 or 432. The forced value at output node 420 during the idle state is independent of the input value at node 410 or the stored value at either node 431 or node 432. In some embodiments, the forced value at output node 420 during the idle state is determined by a value of an input vector as described in FIG. 1 through FIG. 3.

In some embodiments, register 400 is used to force a binary one value at output node 420 during the idle state. For example, when the IDLE* signal is low (logic zero) during the idle state, output node of NAND gate 463, which is also output node 420, is forced to a binary one value.

As described in FIG. 1 and FIG. 2, forcing a forced value based on the value of the input vector to an input of a circuit block such as circuit block 112 of FIG. 1 during an idle state may reduce leakage power in the circuit block during the idle state. Since register 400 may be configured to force a forced value based on the value of the input vector to an input node of a circuit block such as circuit block 112, using register 400 to force an forced value to the input node of a circuit block such as circuit blocks 112 during the idle state may reduce leakage power in the circuit block during the idle state. Further, register 400 may provide a negligible impact on area, delay, and power consumption in the active state when register 400 is used in a circuit unit such as circuit unit 100 of FIG. 1.

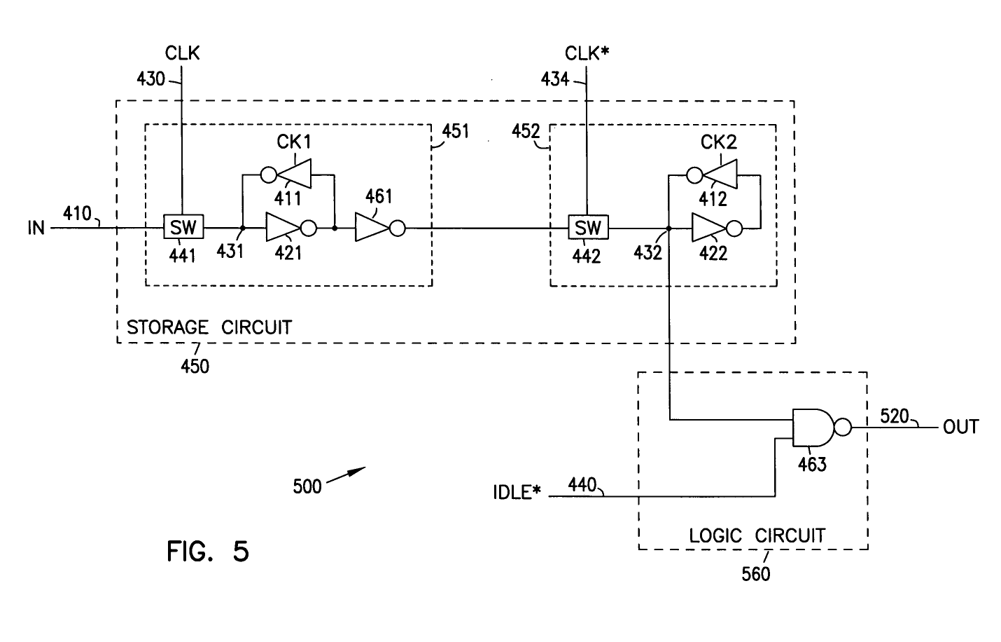

FIG. 5 through FIG. 9 show registers with output gating according to other embodiments of the invention. In FIG. 5 through FIG. 9, features labeled with the same reference numbers as that of FIG. 4 are substantially similar. FIG. 5 shows a register 500. In logic circuit 560 of FIG. 5, inverter 465 (FIG. 4) at one of the input nodes of NAND gate 463 is eliminated. In some embodiments, register 500 is used to force a binary one value at output node 520 during the idle state. For example, when the IDLE* signal is low during the idle state, output node of NAND gate 463, which is also output node 520, is forced to a binary one value.

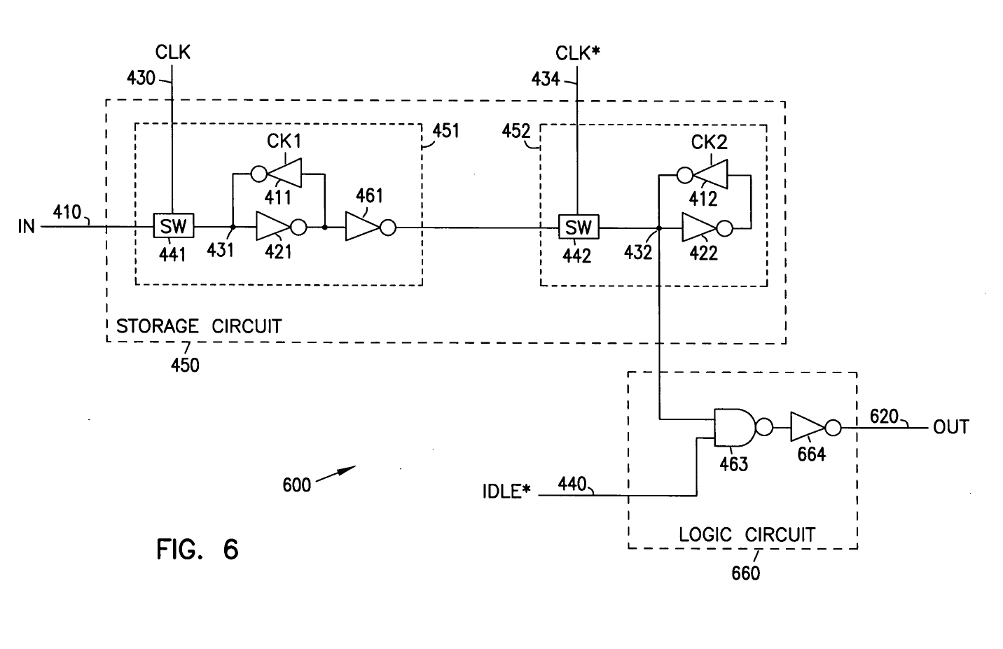

FIG. 6 shows a register 600. In logic circuit 660, an inverter 664 is coupled between the output node of NAND gate 463 and output node 620. In some embodiments, register 600 is used to force a binary zero value at output node 620 during the idle state. For example, when the IDLE* signal is low during the idle state, output node of NAND gate 463 is high causing output node 620 to be low, which corresponds to a binary zero value.

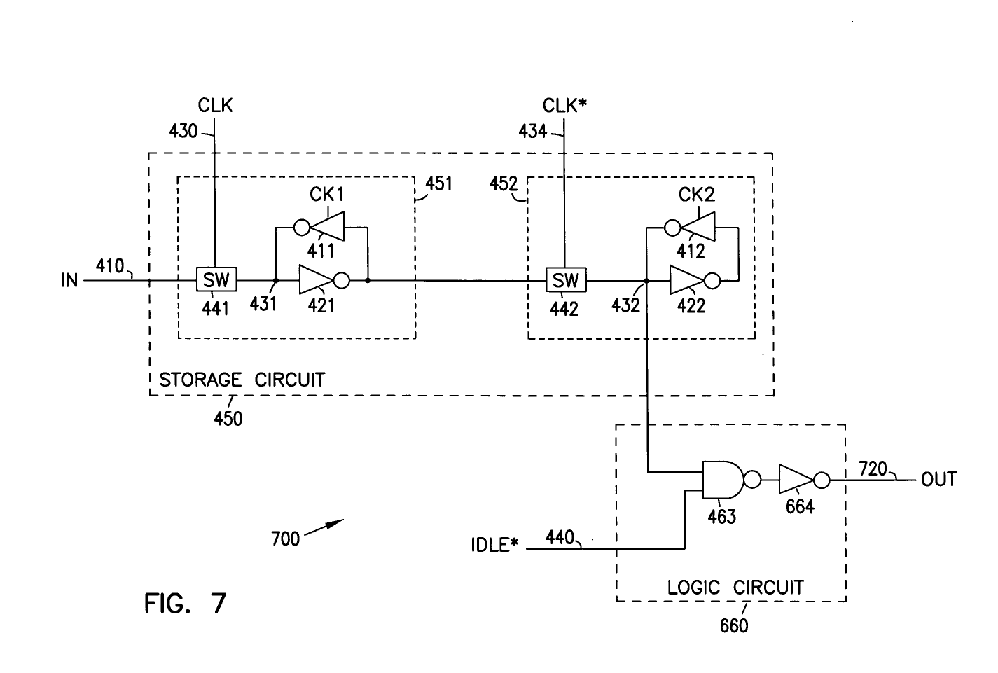

FIG. 7 shows a register 700. In comparison with register 600 of FIG. 6, inverter 461 in first stage 451 is removed from register 700 of FIG. 7. In some embodiments, register 700 is used to force a binary zero value at output node 720 during the idle state. For example, when the IDLE* signal is low during the idle state, output node of NAND gate 463 is high causing output node 720 to be low, corresponding to a binary zero value.

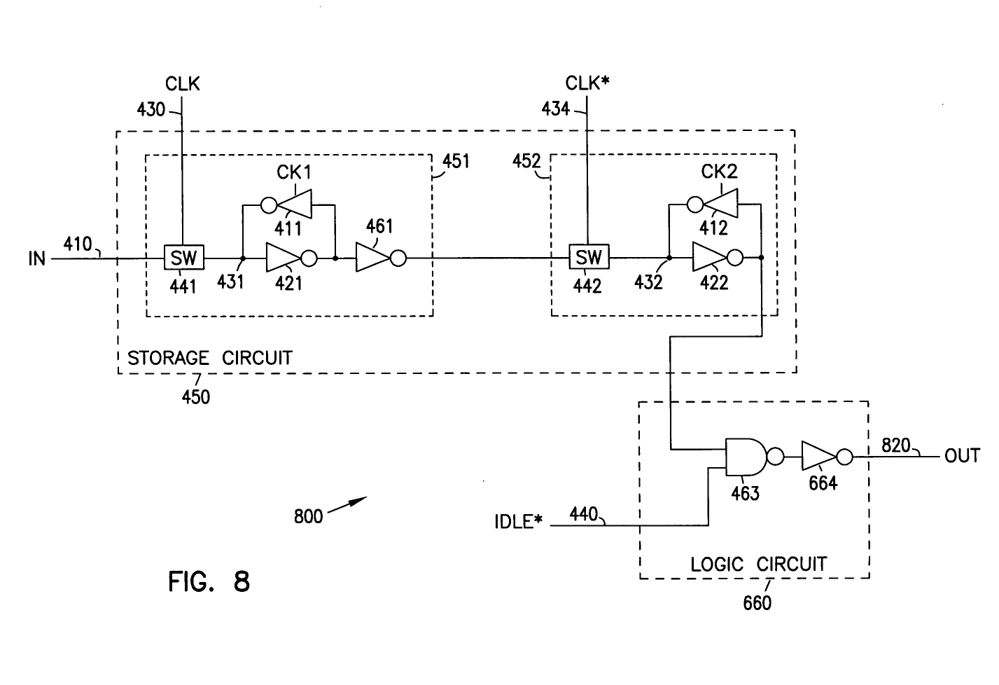

FIG. 8 shows a register 800. In comparison with register 600, one of the input nodes of NAND gate 463 in FIG. 8 is coupled to the output node of inverter 422 in FIG. 8 instead of coupled to the input node of inverter 422 as in register 600 of FIG. 6. In some embodiments, register 800 is used to force a binary zero value at output node 820 during the idle state. For example, when the IDLE* signal is low during the idle state, output node of NAND gate 463 is high causing output node 820 to be low, corresponding to a binary zero value.

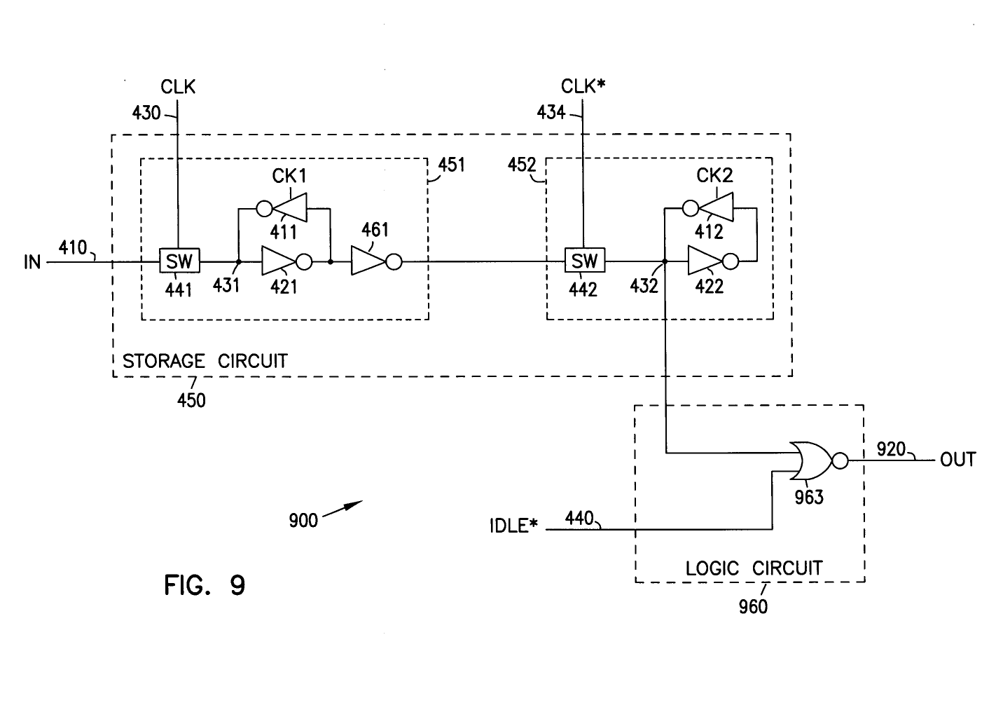

FIG. 9 shows a register 900. In comparison with register 500 of FIG. 5, logic circuit 960 of register 900 of FIG. 9 includes a NOR gate 963 replacing NAND gate 463 in register 500. In some embodiments, register 900 is used to force a binary zero value at output node 920 during the idle state. For example, when the IDLE* signal is low during the idle state, output node of NOR gate 963, which is also output node 920, is forced to a binary zero value.

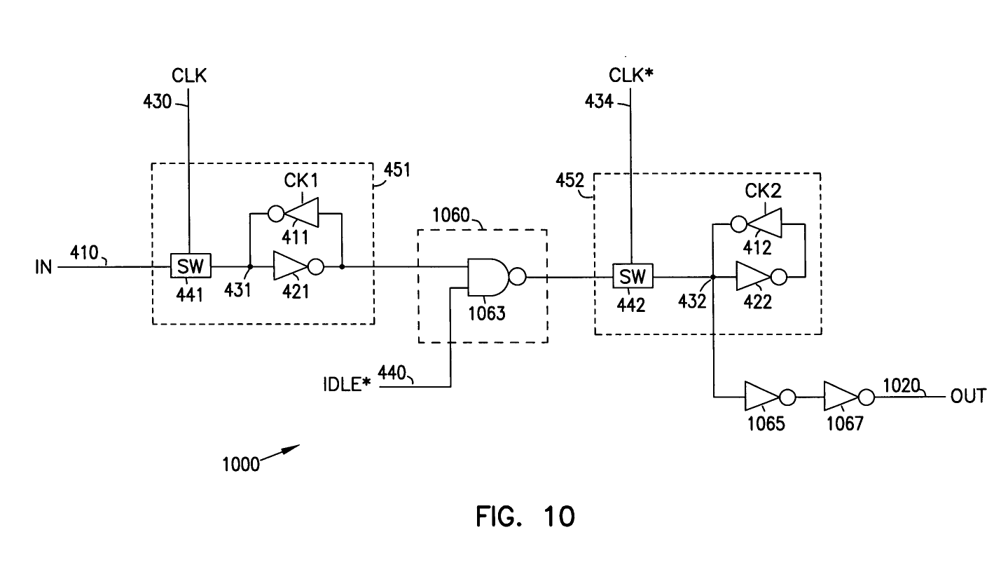

FIG. 10 shows a register with an isolation logic circuit according to an embodiment of the invention. Register 1000 includes a logic circuit 1060 having a NAND gate 1063 located between first stage 451 and second stage 452. One of the input nodes of NAND 1063 is coupled to control node 440 to allow logic circuit 1060 to force a forced value during an idle state to output node 1020 via switch 442 and inverters 1065 and 1067. During the idle state, switch 441 turns off and switch 442 turns on. In register 1000, placing NAND gate 1063 between first stage 451 and second stage 452 and turning off switch 441 allows an isolation between stages 451 and 452 such that the input value may be stored in stage 451 during the idle state and output node 1020 may be restored to a previous output value that existed at output node 1020 before the idle state.

In some embodiments, register 1000 is used to force a binary one value at output node 1020 during the idle state. For example, when the IDLE* signal is low during the idle state, output node of NAND gate 1063 is high causing output node 1020 to be high, corresponding to a binary one value.

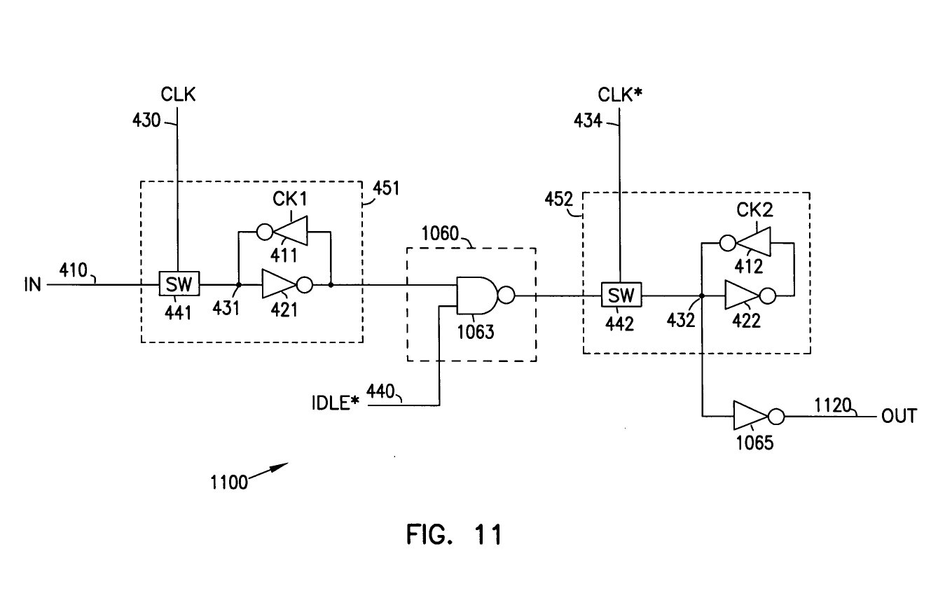

FIG. 11 shows a register with an isolation logic circuit according to another embodiment of the invention. In comparison with register 1000 of FIG. 10, inverter 1067 is removed from register 1100. In some embodiments, register 1100 is used to force a binary zero value at output node 1120 during the idle state. For example, when the IDLE* signal is low during the idle state, output node of NAND gate 463 is high causing output node 720 to be low, corresponding to a binary zero value.

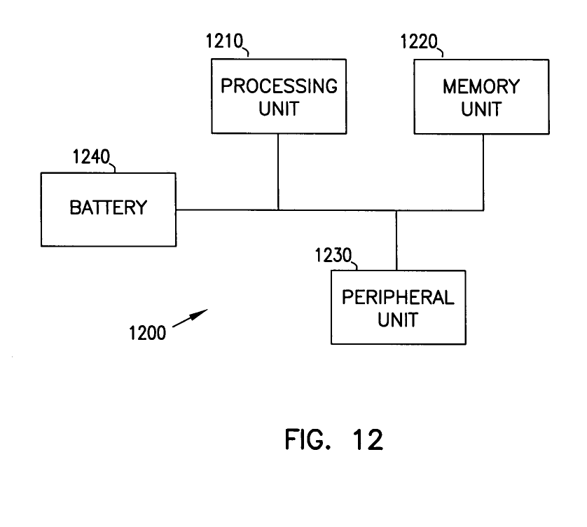

FIG. 12 shows an example of a system according to an embodiment of the invention. System 1200 includes a processing unit 1210 to process instructions, a memory unit 1220 to store information and instructions that may be used by processing unit 1210, a peripheral unit 1230 to perform other functions, and a battery 1240 to provide power to system 1200. In some embodiments, instead of using power from a battery such as battery 1240, system 1200 may use power supplied from an electrical outlet such as a home or office electrical outlet.

In some embodiments, system 1200 is configured to put one or all of units 1210, 1220, and 1230 in an idle state to save power. Any one of the units 1210, 1220, and 1230 may include one or more of the circuit units and registers described in FIG. 1 through FIG. 11. Thus, system 1200 may have a reduced leakage power during the idle state. Therefore, the life of battery 1240 may be extended.

The illustration of system 1200 in FIG. 12 is intended to provide a general understanding of the structure of various embodiments described herein. System 1200 is not intended to serve as a complete description of all the elements and features of systems that might make use of the structures described herein.

System 1200 of FIG. 12 includes computers (e.g., desktops, laptops, hand-helds, servers, Web appliances, routers, etc.), wireless communication devices (e.g., cellular phones, cordless phones, pagers, personal digital assistants, etc.), computer-related peripherals (e.g., printers, scanners, monitors, etc.), entertainment devices (e.g., televisions, radios, stereos, tape and compact disc players, video cassette recorders, camcorders, digital cameras, MP3 (Motion Picture Experts Group, Audio Layer 4) players, video games, watches, etc.), and the like.

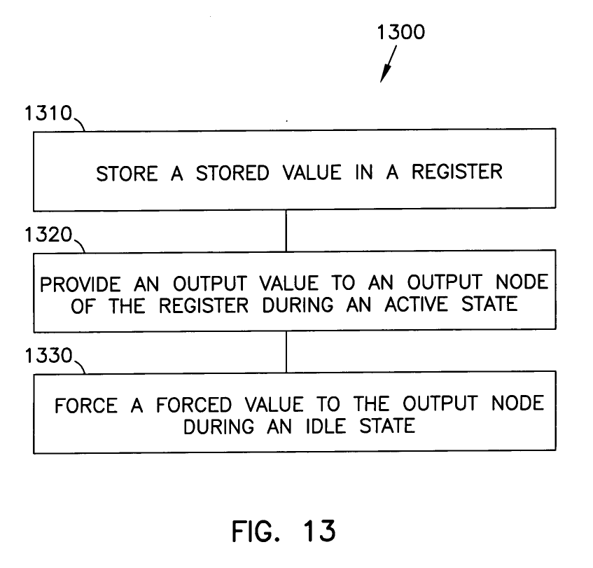

FIG. 13 is a flowchart showing a method according to an embodiment of the invention. In some embodiments, method 1300 is used in the circuit unit, registers, and systems described in FIG. 1 through FIG. 12.

In FIG. 13, activity 1310 stores a stored value in a register. The stored value is based on an input value at an input node of the register during an active state of a circuit unit where the register resides. In some embodiments, the stored value is a copy of the input value or an inversion (complement) of the input value.

Activity 1320 provides an output value to an output node of the register during the active state. The output value during the active state is dependent on the stored value. Since the stored value is based on the input value, in some embodiments, the output value is a copy of the input value or an inversion of the input value.

Activity 1330 forces a forced value to the output node during an idle state of the circuit unit. The forced value is independent of the input value, the stored value, or the output value. In some embodiments, forcing the forced value to the output node of the register during the idle state in method 1300 is performed without altering the input value or the stored value of the register. Further, in some embodiments of method 1300, the forced value is provided at the output node of the register in one clock cycle after the circuit unit switches from the active state to the idle state. In some embodiments, the forced value is a predetermined valued based on a value of an input vector such as the input vector described in FIG. 1. In method 1300, by providing a forced value to the output node of the register in one clock cycle after the circuit unit switches from the active state to the idle state allows the circuit unit to quickly reduce leakage power during the idle state. Activity 1330 may also restore the output node to a previous value. The previous value is the value of the output node before the idle state. In some embodiments, activity 1330 restores the output node to a value based on a new input value received at the input node after the idle state. Using method 1300 in a circuit unit may reduce leakage power in the circuit unit to save power.

The individual activities shown in FIG. 13 do not have to be performed in the order illustrated or in any particular order. Moreover, various activities described with respect to the methods identified herein can be executed in serial or parallel fashion. Some activities may be repeated indefinitely, and others may occur only once. Various embodiments may have more or fewer activities than those illustrated.

The above description and the drawings illustrate some specific embodiments of the invention sufficiently to enable those skilled in the art to practice the embodiments of the invention. Other embodiments may incorporate structural, logical, electrical, process, and other changes. In the drawings, like features or like numerals describe substantially similar devices throughout the several views. Examples merely typify possible variations. Portions and features of some embodiments may be included in, or substituted for, those of others. Many other embodiments will be apparent to those of skill in the art upon reading and understanding the above description. Therefore, the scope of various embodiments is determined by the appended claims, along with the full range of equivalents to which such claims are entitled.

What is claimed is:

1. An apparatus comprising:
a storage circuit including a storage node to store a first value based on an input value received at an input node; and
a logic circuit to receive from a control node a control signal having a value corresponding to an active state and a value corresponding to an idle state, the logic circuit to provide an output value to an output node during the active state, and to provide a second value to the output node during the idle state, wherein the output value is dependent on the first value, and wherein the second value is independent of the first value.

2. The apparatus of claim 1, wherein the logic circuit is configured to restore the output node to a previous output value when the control signal switches from the value corresponding to the idle state to the value corresponding to the active state, and wherein the previous output value corresponds to the output value existed at the output node before the idle state.

3. The apparatus of claim 1, wherein the storage circuit includes a clock node to receive a clock signal having multiple signal levels during the active state and only one signal level during the idle state.

4. The apparatus of claim 3, wherein the logic circuit is configured to provide the second value to the output node in one cycle of the clock signal after the control signal switches from the value corresponding to the active state to the value corresponding to the idle state.

5. The apparatus of claim 1 further comprising a circuit to perform a function based on the output value during the active state, and to receive the second value during the idle state to reduce leakage power in the circuit during the idle state.

6. The apparatus of claim 1, wherein the logic circuit includes a logic gate having a first input node coupled to the storage node, a second input node coupled to the control node, and an output node coupled in series with the output node.

7. The apparatus of claim 1, wherein the logic circuit includes a NAND gate having a first input node coupled to the storage node, a second input node coupled to the control node, and a NAND gate output node coupled to the output node.

8. The apparatus of claim 7, wherein the logic circuit further includes an inverter coupled between the storage node and the first input node of the NAND gate.

9. The apparatus of claim 7, wherein the logic circuit further includes an inverter coupled between the NAND gate output node and the output node.

10. The apparatus of claim 1, wherein the logic circuit includes a NOR gate having a first input node coupled to the storage node, a second input node coupled to the control node, and a gate output node coupled to the output node.

11. The apparatus of claim 1, wherein the logic circuit is configured to provide the second value corresponding to a binary one value during the idle state.

12. The apparatus of claim 1, wherein the logic circuit is configured to provide the second value corresponding to a binary zero value during the idle state.

13. The apparatus of claim 1, wherein the storage circuit includes:
a first stage having a first pair of inverters arranged to create a first stage storage node to store a value based on the input value; and
a second stage having a second pair of inverters arranged to create a second stage storage node to store a value based on the input value, wherein the storage node of the storage circuit is one of the first stage storage node and the second stage storage node.

14. The apparatus of claim 13, wherein the first stage includes a first stage switch coupled between the input node and the first stage storage node, wherein the second stage includes a second stage switch coupled between the first stage storage node and the second stage storage node, and wherein one of the first stage switch and the second stage switch is configured to turn off during the idle state.

15. The apparatus of claim 13, wherein the logic circuit includes a logic gate having a first input node coupled to the first stage storage node, a second input node coupled to the control node, and a gate output node coupled to the second stage storage node.

16. A system comprising:
at least one circuit unit configured to be in an active state and in an idle state, the circuit unit including a plurality of registers, a first register of the plurality of registers including a storage circuit having a storage node to store a value based on a first input value received at a first input node, and a logic circuit to receive a control signal at a control node to provide an output value to an output node of the first register during the active state, and to provide a first value to the output node of the first register during the idle state, wherein the output value is dependent on the value at the storage node, and wherein the first value is independent of the value at the storage node; and
a battery to provide power to the circuit unit.

17. The system of claim 16, wherein a second register of the plurality of registers includes a storage circuit having a storage node to store a value based on a second input value received at a second input node, and a logic circuit to receive the control signal to provide an output value to an output node of the second register during the active state, and to provide a second value to the output node of the second register during the idle state, wherein the output value of the second register is dependent on the value at the storage node of the second register, wherein the second value at the output node of the second register is independent of the value at the storage node of the second register, and wherein the second value at the output node of the second register is independent of the first value at the output node of the first register.

18. The system of claim 17, wherein the circuit unit further includes a combinational circuit having a first input node to receive the output value of the first register during the active state and to receive the first value at the output node of the first register during the idle state, and a second input node to receive the output value of the second register during the active state and to receive the second value at the output node of the second register during the idle state.

19. The system of claim 17, wherein the first register is configured to restore the output node of the first register to the output value existed at the output node of the first register before the idle state, and wherein the second register is configured to restore the output node of the second register to the output value existed at the output node of the second register before the idle state.

20. The system of claim 19, wherein the first register is configured to provide the first value corresponding to one of a binary one value and a binary zero value during the idle state, and wherein the second register is configured to provide the second value corresponding to one of a binary one value and a binary zero value during the idle state.

21. A method comprising:
storing a first value in a register of a circuit unit based on an input value received at an input node of the register during an active state;
providing an output value to an output node of the register during the active state, wherein the output value is dependent on the first value; and
forcing a second value to the output node during an idle state, wherein the second value is independent of the first value.

22. The method of claim 21 further comprising:
restoring the output node to a previous output value when the circuit unit goes to the active state from the idle state, wherein the previous output value corresponds to the output value existed at the output node before the idle state.

23. The method of claim 21 further comprising:
providing the output value to an input node of a combinational circuit during the active state; and
providing the second value to the input node of the combinational circuit during the idle state to reduce leakage power in the combinational circuit during the idle state.

24. The method of claim 23, wherein the second valued is determined based on a structure of the circuit unit.

25. The method of claim 21, wherein forcing the second value to the output node during the idle state is performed without altering the input value and the first value.

26. The method of claim 21, wherein the second value is provided to the output node in one clock cycle after a control signal switches from a first signal level to a second signal level to indicate a switch from the active state to the idle state.
